(19) United States
(12) Patent Application Publication
(10) Pub. No.: US 2018/0346371 A1
(43) Pub. Date: Dec. 6, 2018

(54) SILVER CONDUCTIVE PASTE COMPOSITION

(71) Applicant: SUN CHEMICAL CORPORATION, Parsippany, NJ (US)

(72) Inventor: Jerome MOYER, Englewood, NJ (US)

(73) Assignee: SUN CHEMICAL CORPORATION, Parsippany, NJ (US)

(21) Appl. No.: 15/780,505

(22) PCT Filed: Dec. 9, 2016
(86) PCT No.: PCT/US2016/065738

§ 371 Date: May 31, 2018

Related U.S. Application Data
(60) Provisional application No. 62/265,461, filed on Dec. 10, 2015.

(51) Int. Cl. C03C 8/18; C03C 8/02; C03C 4/14; H01L 31/0224; H01B 1/22; H01L 29/45

(52) U.S. Cl. CPC C03C 8/18; C03C 8/02; C03C 4/14; C03C 2209/00; H01B 1/22; H01L 29/456; C03C 2204/00; H01L 31/022425

(57) ABSTRACT

Described herein is a conductive composition that includes a silver powder, an organic medium, an optional inorganic additive, elemental thallium and/or a thallium containing compound, elemental tellurium and/or a tellurium containing compound, and optionally, a glass frit. The composition may be a paste. Other inorganic additives and glass may be present in the composition. Further described are devices such as semiconductors, photovoltaic devices, and solar cells in which the substrates thereof are coated with the conductive compositions. Such devices exhibit improved efficiency.

### CROSS REFERENCE TO RELATED APPLICATIONS

This application claims priority to U.S. Provisional Patent Application Ser. No. 62/265,461 filed Dec. 10, 2015 which is incorporated herein by reference in its entirety and for all purposes.

### FIELD OF THE INVENTION

The present invention is directed to a silver conductive paste that may be used in photovoltaic devices such as solar cells, optically reflective applications, sealing glass pastes, etchant pastes, conductive pastes used for shielding purposes and for carrying electrical current in electronic circuit or inductive applications.

### BACKGROUND OF THE INVENTION

Electrical contacts for solar cells are provided by the formation of electrodes on a silicon wafer by applying and firing a silver paste thereon. In order to minimize the circuit's electrical resistance, maximize the electrical current and voltage output and thus increase the cell power output and efficiency, typically a glass is incorporated into the silver paste such that the glass can enable an electrical contact with the silicon by etching away an insulating coating present on the silicon wafer.

US 2014/0021417 describes a silver electrode-forming paste that contains a silver powder, a glass component and an organic medium wherein the glass component contains a tellurium loaded glass frit.

EP 2 617 689, U.S. Pat. No. 8,969,709 B2, and U.S. Pat. No. 8,497,420 B2 describe the use of lead and tellurium oxides in conductive compositions and pastes.

U.S. Pat. No. 8,889,980 discloses thick film pastes containing lead, tellurium and lithium oxides and their use in the manufacture of semiconductor devices.

U.S. Pat. No. 8,308,993 discloses conductive inks substantially free of glass frit and containing metallo-organic components including thallium.

### SUMMARY OF THE INVENTION

Described herein is a conductive composition that includes a silver powder, an organic medium, an optional inorganic additive, elemental thallium and/or a thallium containing compound, elemental tellurium and/or a tellurium containing compound, and optionally, glass frit.

Further described is an inventive device having a substrate coated with the conductive composition described herein.

Still further, described is a process for preparing a device comprising:
a) applying the coating composition described herein to a surface of a substrate of a device; and
b) drying the composition.

In one aspect, the conductive composition is a conductive paste. In a particular aspect, the paste may be a sealing glass paste, an etchant paste, a conductive paste used for shielding purposes and for carrying electrical current in electronic circuit or inductive applications.

In one aspect, the device is a photovoltaic device such as solar cell.

In another aspect, the device is a semiconductor device.

In one aspect, a lesser amount of glass is present in the conductive composition described herein than compared to state of the art compositions. This may result from including inorganic additive in the conductive composition, which may reduce the contact resistance between the conductive composition and the device, e.g., a silicon solar cell.

These and other objects, advantages, and features of the invention will become apparent to those persons skilled in the art upon reading the details of the methods and formulations as more fully described below.

Commonly owned International Application No. PCT/US16/38010, filed under the Patent Cooperation Treaty (PCT) on Jun. 17, 2016, is incorporated herein by reference in its entirety.

### BRIEF DESCRIPTION OF THE DRAWINGS

FIG. 1 shows the high R² value, correlating the R_{S} to the FF for the conductive pase compositions of Example 3 indicating that cell efficiencies were driven by the series resistance associated to paste formulation.

FIG. 2 shows the adhesion properties vs. the % wt of glass frits for conductive compositions of Example 4.

### DETAILED DESCRIPTION

It is to be understood that the foregoing general description and the following detailed description are exemplary and explanatory only, and are not restrictive of any subject matter claimed.

Unless otherwise defined, all technical and scientific terms used herein have the same meaning as is commonly understood by one of skill in the art to which the inventions belong. All patents, patent applications, published applications and publications, websites and other published materials referred to throughout the entire disclosure herein, unless noted otherwise, are incorporated-by-reference into the present disclosure in their entirety for any purpose.

### Definitions

In this application, the use of the singular includes the plural unless specifically stated otherwise. As used herein, the singular forms “a,” “an” and “the” are intended to include the plural forms as well, unless the context clearly indicates otherwise.

“Or” means “and/or”, unless stated otherwise.

“Comprises” and/or “comprising” specify the presence of the stated features, integers, steps, operations, elements, and/or components, but do not preclude the presence or addition of one or more other features, integers, steps, operations, elements, components, and/or groups thereof. Furthermore, to the extent that the terms “includes,” “having,” “has,” “with,” “composed,” “comprised” or variants thereof are used in either the detailed description or the claims, such terms are intended to be inclusive in a manner similar to the term “comprising.”

Ranges and amounts can be expressed as “about” a particular value or range. “About” is intended to also include the exact amount. For example, “about 5 percent” means “about 5 percent” and also “5 percent” of the thing in issue (e.g., the amount a component is present in weight %). “About” means within typical experimental error for the application or purpose intended.

The present invention is directed to conductive compositions, such as conductive paste compositions, that provide thick film electrodes in a solar cell.

It has been found that high efficiency cells can be produced by using the inventive conductive compositions, e.g., pastes that include inorganic additive, when compared to the efficiency of cells prepared from conductive compositions that require greater amounts of glass in the compositions. Particular advantages may be achieved when the inorganic additive includes elemental thallium and/or a thallium compound and/or elemental tellurium and/or a tellurium compound.

In one aspect, the inventive conductive compositions, e.g., pastes, comprise an electrically conductive metal, e.g., silver, an organic medium, an optional inorganic additive, elemental thallium and/or a thallium containing compound, elemental tellurium and/or a tellurium containing compound, and optionally, glass frit. While the conductive compositions may be glass free, in another aspect, the compositions may include glass, e.g., glass frit. When present, glass frit may be present in an amount of about 0.01 wt % to about 5.0 wt %, preferably in an amount of about 0.05 wt % to about 2.5 wt %, and more preferably in an amount of about 0.1 wt % to about 2.0 wt %, and most preferably about 0.1 wt % to <about 0.5 wt %, based on the total weight of the conductive paste composition. In a further aspect, the conductive compositions described herein may be essentially glass free.

In one aspect, the glass frit includes elemental thallium and/or a thallium containing compound (referred to hereafter in some instances as “thallium component”) as a glass frit component. In another aspect, the glass frit includes elemental tellurium and/or a tellurium containing compound (referred to hereafter in some instances as “tellurium component”) as a glass frit component. In yet another aspect, the glass frit includes a thallium component and a tellurium component as glass frit components.

In one aspect, the inorganic additive includes a thallium component as an inorganic additive component. In another aspect, the inorganic additive includes a tellurium component as an inorganic additive component. In yet another aspect, the inorganic additive includes a thallium component and a tellurium component as inorganic additive components.

In yet another aspect a thallium component and a tellurium component are components of the inorganic additive and glass frit.

In one aspect, the conductive composition may be in the form of a paste, although other compositions forms may be prepared. For the sake of simplicity, the inventive conductive composition shall be hereinafter described as conductive paste compositions.

In one aspect, the inorganic additive may include one or more of a lead compound and a bismuth compound. Examples of such compounds include the oxides and salts of lead and bismuth. The inclusion of these components in the conductive paste may improve silicon solar cell performance by improving the contact of an electrode to the cell and increasing the conversion efficiency, e.g., the light conversion efficiency of the solar cell.

In one aspect, the ratio, on a weight percent (wt %) basis, of the tellurium component to the thallium component in the inventive conductive paste compositions is about 0.6 to about 93 (the molar ratio for same is about 2 to about 265).

In one aspect, inorganic additives may be crystalline forms of oxides and salts. The term “inorganic additive” refers to one or more additives that are not associated, incorporated or “bound” within a glass. Thus, while the raw materials that go into making glass may consist of inorganic compounds, the final glass form, wherein some degree of an amorphous material is present, are not to be considered inorganic additives as used herein. It is not intended that the term “inorganic additive” embrace the silver component of the present compositions.

The term “glass” refers to a milled “glass frit” powder that may be employed in preparing the conductive paste compositions described herein. Molten glass is quenched in water and the resulting quenched beads of glass are referred to as “glass frit” or “frit”, which is further milled to reduce it into a fine powder. The milled powder is also referred to herein as “glass” or “glass frit”.

Also glassy materials, e.g., those materials that constitute the glass may be described herein as “bound” and typically have an amorphous to semi-amorphous structure, which may or may not be stoichiometric in nature.

Consequently, the thallium component, the tellurium component, the lead compound and/or the bismuth compound, for example, when bound and co-mingled in glass, may provide the glass with properties that are distinct and measurably different from their non-bound, or “free” forms. In one aspect, the oxides of these components/compounds are present in the glass, and improve the glass properties, and by extension, the properties of the conductive paste compositions.

The inclusion of the thallium component and the tellurium component in glass frits that are included in the conductive paste composition may improve the electrical contact between the composition and a silicon solar cell, e.g., the substrate of the solar cell, which may improve solar cell efficiency. In one aspect the thallium component is thallium oxide and tellurium component is tellurium oxide.

Still further, the inclusion of the lead oxide, bismuth oxide, the thallium component and tellurium component in the glass of the conductive paste composition may improve the electrical contact between the paste and a silicon solar cell, which may improve efficiency of the solar cell. In one aspect the thallium component is thallium oxide and tellurium component is tellurium oxide.

In one aspect, the weight percent of glass/glass frits in the inventive conductive paste compositions are less than the amount at which glasses are included in state of the art compositions, which include at least 0.5 wt % glass.

In one aspect, the compositions of the present invention are essentially glass-free. Furthermore it has been found that good solar cell efficiency is attained in which inventive conductive pastes include lithium-free glass, in an amount of about 0.27 wt %.

Comparable cell efficiencies are achieved using conductive paste compositions based on free state material forms of TeO₂, TIO₂, PbO, and Bi₂O₃ to pastes made with highly bound materials, which use glass to make electrical contact to the cell.

“Comparable” as used herein when referring to light conversion efficiency, means a ±0.6% absolute difference in light conversion efficiency. Test-to-test variability may account for the majority of this variation. Test-to-test variability derives from the accumulated influences that may include changes in silicon wafer quality, wafer processing, paste printing and firing and/or measurement variance. Within a single test, where all wafers originate from the same source and are processed into cells and are tested concurrently, “Comparable light conversion efficiency” refers to within a ±0.2% absolute difference in same. Accordingly the present invention provides a conductive composition, typically in the form of a thick-film silver paste which comprises a silver powder, an organic medium/organic vehicle and discrete inorganic additives in a free state comprising a thallium component and a tellurium component.

The conductive inventive paste compositions exhibit an excellent set of properties when used as, for example, an electrode-forming conductive paste in a device, such as for example a photovoltaic device, such as a solar cell. Solar cells having electrodes formed from the inventive paste compositions exhibit a markedly improved efficiency in converting light energy into electrical energy. When employed as glass frit component and/or as inorganic additive component, the thallium component may be a thallium containing compound, such as for example an organothallium compound, thallium (I) oxide, thallium (III) oxide, thallium(I) bromide, thallium(I) carbonate, thallium(I) oxalate, thallium(I) iodide, thallium(I) fluoride, thallium(I) nitrate, thallium(I) sulfate, thallium(I) ethoxide, thallium(III) acetate, thallium(III) trifluoroacetate, thallium(I) hexafluorophosphate, thallium(I) 2-ethylhexanoate and/or thallium(I) hexafluoro-2,4-pentanedionate. The thallium component may also be elemental thallium, and a mixture of any of the above.

When employed as glass frit component and/or as inorganic additive component, the tellurium component may be one or more of telluric acid, diisopropyl telluride, tellurium ethoxide, tellurium isopropoxide, antimony telluride, barium telluride, bismuth telluride, lanthanum telluride, lead (II) telluride, lithium telluride, manganese(II) telluride, manganese(IV) telluride, molybdenum telluride, nickel tellurate, nickel telluride, rhenium telluride, rhodium telluride, silver telluride, thallium telluride, titanium telluride, tungsten telluride, zinc telluride, tellurium bromide (TeBr₄) tellurium chloride (TeCl₄) tellurium iodide (TeI₄), and tellurium oxide (TeO₂). The tellurium component may also be elemental tellurium, and a mixture of any of the above.

The composition may include the tellurium component in an amount of about 0.1 to 0.75 wt %.

The composition may include about 0.01 wt % to about 5 wt % of thallium component and preferably about 0.01 wt % to about 1.0 wt % of same.

The inorganic additive may include a compound or material selected from a chalcogenide, a pnicogenide, or a halide, Ag₂Te, AgAsF₆, Ag₃AsO₄, AgBF₄, AgBr, AgCl, AgClO₄, AgF, AgF₂, AgHF₂, AgI, Ag₂MoO₄, AgPF₆, AgPO₄, AgReO₄, Ag₂SO₄, Ag₂S, AgSbF₆, AgVO₃, Ag₂WO₄, Al₂O₃, As₂O₃, AuTe₂, BaO, B₂O₃, BaF₂, BaO, Bi, BiBr₃, BiCl₃, BiF₃, Bi₄Ge₃O₁₂, BiI₃, Bi₂MoO₆, Bi₂Mo₃O₁₂, Bi₂O₃, Bi(OH)₃, BiSb, Bi₂Se₃, Bi₂S₃, Bi₂Te₃, BiVO₄, Bi₂(WO₄)₃, C₂O₃, CaO, CdO, CoO, CuO, Cu₂O, Ga₂O₃, In₂O₃, KAg₄I₅, LaF₃, La₂O₃, Li₂O, Li₃PO₄, MgO, Mn₂O₅, MnO₂, Mo₂O₃, NiO, P₂O₅, Pb, PbBr₂, PbCl₂, PbF₂, PbHPO₄, PbI₂, PbO, PbSO₄, PbSe, PbS, PbSb, PbTe, Pb(VO₃)₂, ReO₂, ReO₃, Re₂O₇, RuO₂, Sb₂O₃, SeO₂, SO₂, SO₃, SiO₂, SnO₂, SrF₂, SrO, Tb₂O₃, Tb₄O₇, TeBr₄, TeCl₄, TeI₄, TeO₂, TiO₂, TlF, Tl₂O₃, OsO₄, V₂O₅, WO₃, Y₂O₃, ZnO, ZnTe, ZrO₂, and combinations thereof.

Preferably the inorganic additive comprises a one or more of a lead compound, a bismuth compound, a thallium component, a tellurium component, and combinations thereof. Preferably the inorganic additive comprises lead oxide, bismuth oxide, thallium oxide, and tellurium oxide.

In one aspect, the inventive conductive paste compositions include between about 0.1 wt % to about 5.0 wt % inorganic additive. More preferably, the inventive conductive paste compositions include inorganic additive in an amount of about 0.5 wt % to about 4.0 wt %.

In one aspect, the inventive paste composition includes about 0.05 wt % to about 2.5 wt % lead oxide, preferably between about 0.1 wt % to about 0.75 wt % lead oxide.

In one aspect, the inventive paste composition includes about 0.05 wt % to about 2.5 wt % tellurium oxide, preferably between about 0.1 wt % to about 2.0 wt % tellurium oxide, more preferably about 0.1 wt % to about 0.75 wt % tellurium oxide.

In one aspect, the inventive paste composition includes about 0.01 wt % to about 2.5 wt % bismuth oxide and preferably about 0.05% to about 0.5 wt % bismuth oxide.

In one aspect, the inventive paste compositions include about 0.01 wt % to about 5.0 wt % of glass frit, preferably about 0.05 wt % to about 2.5 wt % of glass frit, more preferably about 0.1 wt % to about 2 wt % glass frit, even more preferably 0.1 wt % to about <0.5 wt % of glass frit, based on the total weight of the conductive paste composition. As indicated above, the inventive paste compositions may be glass free or be essentially glass free.

Typically glass frits are added to the paste compositions to etch through the insulating oxide-, nitride- or carbide-based anti-reflective coating (ARC), and layer(s) on the surface of the silicon wafer.

When glass frit is included in the conductive paste compositions, one or more of the following may be present in the glass frit: Ag₂Te, AgAsF₆, Ag₃AsO₄, AgBF₄, AgBr, AgCl, AgClO₄, AgF, AgF₂, AgHF₂, AgI, Ag₂MoO₄, AgPF₆, AgPO₄, AgReO₄, Ag₂SO₄, Ag₂S, AgSbF₆, AgVO₃, Ag₂WO₄, Al₂O₃, As₂O₃, AuTe₂, BaO, B₂O₃, BaF₂, BaO, Bi, BiBr₃, BiCl₃, BiF₃, Bi₄Ge₃O₁₂, BiT₃, Bi₂MoO₆, Bi₂Mo₃O₁₂, Bi₂O₃, Bi(OH)₃, BiSb, Bi₂Se₃, Bi₂S₃, Bi₂Te₃, BiVO₄, Bi₂(WO₄)₃, C₂O₃, CaO, CdO, CoO, CuO, Cu₂O, Ga₂O₃, In₂O₃, KAg₄I₅, LaF₃, La₂O₃, Li₂O, Li₃PO₄, MgO, Mn₂O₅, MnO₂, Mo₂O₃, NiO, P₂O₅, Pb, PbBr₂, PbCl₂, PbF₂, PbHPO₄, PbI₂, PbO, PbSO₄, PbSe, PbS, PbSb, PbTe, Pb(VO₃)₂, ReO₂, ReO₃, Re₂O₇, RuO₂, Sb₂O₃, SeO₂, SO₂, SO₃, SiO₂, SnO₂, SrF₂, SrO, Tb₂O₃, Tb₄O₇, TeBr₄, TeCl₄, TeI₄, TeO₂, TiO₂, TlF, Tl₂O₃, OsO₄, V₂O₅, WO₃, Y₂O₃, ZnO, ZnTe, and ZrO₂

In one aspect, the glass frit comprises a lead compound, a tellurium compound, a bismuth compound and/or a thallium compound. In another aspect, the glass frit includes both lead oxide and tellurium oxide, in another aspect the glass frit contains lead oxide, tellurium oxide, bismuth oxide and a thallium compound, e.g., thallium oxide.

In one aspect, the glass frit comprises about 5 wt % to about 60 wt % lead oxide, preferably about 10 wt % to about 50 wt % lead oxide.

In one aspect, the glass frit comprises about 20 wt % to about 70 wt % tellurium oxide, preferably about 10 wt % to about 60 wt % tellurium oxide.

In one aspect, the glass frit comprises about 5 wt % to about 20 wt % bismuth oxide, preferably about 10 wt % to about 15 wt % bismuth oxide.

In one aspect, the glass frit comprises about 1 wt % to about 60 wt % thallium oxide, preferably about 1 wt % to about 50 wt % thallium oxide.

In one aspect, the inventive conductive paste composition includes silver powder as the conductive material. The silver powder may have an average specific surface area (SSA) of about 0.6 m²/g to about 1.5 m²/g and preferably has a particle size D50 of about 0.1 μm to about 5 μm, and more preferably of about 0.5 μm to about 2 μm.

The silver powder is not limited in morphology and may be spherical, elliptical, etc. and typically may be thermally sintered to form a conductive network during a solar cell metallization firing step.

Furthermore the silver powder may be pre-coated with different surfactants to avoid particle agglomeration and aggregation. The surfactant may be a straight-chain, or branched-chain fatty acid, a fatty acid ester, fatty amide or mixtures thereof.

Two or more silver powders may be included in the inventive conductive paste compositions. When this is the case, a higher silver particle packing density may be attained, and the proximity of the silver particles to each other facilitates silver densification during the firing process. This results in a more connected conduction path, which may improve the solar cell efficiency.

The silver powder preferably has a purity of greater than 99.5%. Impurities such as Zr, Al, Fe, Na, Cl, K, and Pb may be present. Preferably, the impurity concentration of any one impurity is less than about 100 ppm.

The conductive paste compositions according the present invention may include silver powder in an amount of about 40 wt % to about 98 wt %, preferably about 70 wt % to about 95 wt %, and more preferably about 87 wt % to about 93 wt %.

The conductive paste compositions include about 1 wt % to about 10 wt % of the organic medium, preferably about 2 wt % to about 8 wt % of organic medium, and more preferably about 4 wt % to about 6 wt % of organic medium.

In one aspect, the organic medium includes resin, rosin and/or a solvent.

In one aspect, the resin is selected from one of acrylic resin, epoxy resin, phenol resin, alkyd resin, cellulose polymers, polyvinyl alcohol, rosin, and combinations thereof. Preferably, the resin is hydroxypropylcellulose (HPC), hydroxyethylcellulose (HEC), or a combination thereof.

In one aspect, the organic medium comprises about 0.2 wt % to about 2 wt % resin or rosin, preferably about 0.5 wt % to about 1.5 wt % resin or rosin.

The solvent may be Texanol® (common name: 2,2,4-trimethyl-1,3-pentanediol monoisobutyrate), propanol, isopropyl alcohol, ethylene glycol, diethylene glycol derivatives, toluene, xylene, dibutyl carbitol, terpineol, and mixtures thereof.

The solvent may also be dimethylethanolamine (2-(dimethylamino) ethanol, 2-aminoethanol (ethanolamine), 1, 2-propanediol (propylene glycol), 1, 3-butanediol, diethylene glycol, dipropylene glycol, aniline, water, glycerol, 1, 5-pentanediol, benzyl alcohol, 3-methylphenol (m-Cresol), and mixtures thereof.

In one aspect, the solvent has a surface tension greater than 35 dyne/cm, and the organic medium includes about 2 wt % to about 80 wt % of solvent.

The conductive paste compositions may further comprise a thixotropic agent which may be cellulose polymer, ethyl cellulose, hydroxyethyl cellulose, castor oil, hydrogenated castor oil, an amide modified castor oil derivative, a fatty amide, and combinations thereof.

Suitable thixotropic agents can be obtained from Rockwood Additives, Cray Valley, or the Troy Corporation.

The conductive paste compositions may also include a dispersant, for example, a long-chain fatty acid, such as, for example, a stearic acid with a functional amine group, acid ester, alcohol groups, and combinations thereof.

Suitable commercially available dispersants include BYK 108, BYK 111, Solsperse 66000 and Solsperse 27000, which can be obtained from Akzo Nobel, Byk, Lubrizol or Elementis.

For rheology modification of the inventive conductive paste compositions, one or more long chain alcohols may be included therein. Examples of such products include the Isofol® products commercially available from Sasol.

As indicated, one inventive aspect is that the inventive compositions are conductive paste compositions. The conductive paste compositions may have a viscosity of about 50 Pa*s to about 250 Pa*s at 10 reciprocal seconds and 25° C., using a 20 mm diameter, 0 degree cone and plate system. Viscosity tests can be made with an AR-2000 Rheometer, as sold by TA Instruments, or an equivalent piece of equipment.

Another inventive aspect of the present disclosure is a method for making the inventive conductive paste compositions described herein.

Yet another inventive aspect of the present disclosure is a coated substrate comprising a substrate coated with the inventive conductive paste compositions described herein. Still yet another inventive aspect is a method of preparing a coated substrate with the inventive conductive paste compositions described herein.

In one aspect, the substrate may comprise semiconductor material, such as, for example, a silicon-containing semiconductor material. In another aspect, the semiconductor material is a silicon wafer that is employed as a substrate.

The inventive conductive paste compositions may be used to provide front contact electrodes for crystalline silicon solar cells wherein the substrate is a silicon wafer.

The process for preparing a coated substrate comprises
a) applying a conductive paste composition according to the present invention to a surface of the substrate and
b) drying the composition.

The conductive paste compositions may be prepared by forming an organic vehicle by combining organic resins, rosins and solvents, and mixing the organic vehicle with one or more of dispersants, thixotropic agents, and alcohols.

The consistency of the organic vehicle is usually in the form of paste with a viscosity preferably between 50 to 250 Pa*s at 10 reciprocal seconds on a cone and plate system measured using a TA Rheometer or equivalent piece of equipment.

During the firing of the silicon wafer, it is desirable that the organic resins and rosins burn off during the firing, thereby leaving no residues on the wafer. The organic resins and rosins included in the organic medium may be chosen to attain this outcome.

The solvent should be able to dissolve the resins, rosins, and thixotropic agents, and preferably is capable of aiding the print quality conductive paste compositions. The solvent should evaporate during the subsequent drying step.

In another inventive aspect, described is a process for making a solar cell having electrodes printed thereon. The process comprises applying a coating of the inventive conductive paste composition onto the front side surface of a silicon wafer as the anode side. The coated silicon wafer is then fired. In another inventive aspect, the process for making a solar cell further comprises applying overlapping layers comprising aluminum and silver to the back side surface of the silicon wafer as the cathode side. The coated silicon wafer is then fired. The number of overlapping layers may be two (2).

The inventive conductive paste composition may be deposited on a silicon wafer by screen printing same through a stainless steel mesh screen. Stroke movement across the screen provides a high shear rate that thins the viscoelastic conductive paste composition as it rolls over and passes through micro-channels of mesh pattern of the screen. The size of the micro-channels is mesh type dependent. Mesh size may be about 200 wires to about 400 wires per inch. It is desirable that the fine grid lines, or “fingers”, be as narrow as possible to leave more open area for sunlight collection, while also being wide enough to maintain good print quality. The height of the printed fingers may be about 10 microns to about 35 microns. Taller fingers that are continuous, without roughness or valleys, may advantageously reduce the resistance to current, and also may advantageously improve the efficiency of the solar cell.

In one aspect in which the inventive conductive paste compositions are used in the manufacture of crystalline silicon solar cells, solar cell manufacturers may begin with doped silicon wafers of either p-type or n-type.

With regard to a p-type wafer, the wafer may be doped with p-type elements such as boron at concentrations of approximately about 10¹⁶ atoms/cm³. The wafer is preferably chemically cleaned to reduce impurities that could impact the optical or electrical properties of the silicon. The wafer may then be chemically textured to make it less reflective, thereby improving its light capturing capabilities. The wafer is then exposed to an n-type dopant, such as phosphorus, in either a gaseous or liquid state. The n-type dopant diffuses into the silicon wafer at temperatures up to 1000° C. Following diffusion, a surface “phos-glass” layer is chemically removed to expose the doped silicon surface underneath. Phosphorus concentrations remaining at the surface of the wafer are on the order of about 1 to about 10E×10²⁰ atoms/cm³, or about 1 phosphorous atom for every 1,000 to 10,000 silicon atoms.

The phosphorous concentration drops off below the surface, as is common to a diffusion profile in a solid, until it reaches the same concentration as the boron dopant, typically at a depth of about 100 nm to about 300 nm. The depth of this net-zero charge is the location of the diode, whereby electrical charges preferentially flow in one or the other direction based on the sign of the charge. In this way, the conductive electrons are captured by the emitter to diffuse to the anode.

Preferably, a step to provide electrical isolation is performed since the top, bottom and side edges may have the n-type dopant diffused into them. The “positive” side may be isolated from the “negative” sides of the cell by chemically removing the doped material from the edges of the wafer and from the back-side of the cell.

The optical and electrical qualities of the wafer may be improved by depositing dielectric materials such as, for example, H:SiNₓ and/or SiOₓ on the light receiving surface(s) of the wafer at a total thickness of about 70 angstroms to about 120 angstroms. A film of this material may serve as an anti-reflective coating (ARC) to the silicon. The hydrogen from the ARC layer may passivate dangling electric bonds at the surface and grain boundaries of the silicon.

At this point the wafer has properties of a working solar cell. When light shines on the wafer, electrical current will flow and a voltage difference can be measured between the opposing wafer surfaces. To extract the current and voltage (power) from the cell, electrodes are screen printed onto the wafer.

A conductive paste employed in providing back bus bars is printed onto a minor area on the backside of the wafer (e.g., cell). The back bus bar paste is then dried by heating the cell to about 250° C., which volatilizes the solvents in the paste and results in their removal therefrom.

A less conductive paste, for example, an aluminum paste, is printed on the remaining backside area of the wafer. The printed aluminum paste layer overlaps the edges of the bus bar paste so that current delivered to the bus bar pads may disperse to the full rear face of the cell. The aluminum paste is then dried.

A conductive paste composition in accordance with the present invention is screen printed in a grid-like pattern on the front (e.g., light-exposure) side of the cell. Narrow silver grid lines on the screen, which are preferably less that 40 μm wide, are narrowly spaced at a separation of about 1.4 mm to maximize the amount of light incident on the silicon while reducing the in-plane resistance of electrons that will flow through the emitter on their way to being collected by the silver anode material.

The combination of silver powders and organic ingredients is intended to print through the narrow passages without interrupting the fine lines formed from the steel mesh of the screen. Having a sufficient amount of silver be transferred in continuous lines so that the grid lines themselves give minimal resistance to the current flow is the objective. To attain sufficient transfer of silver and to minimize resistance and line spreading, a high aspect ratio, e.g., line height divided by line width, of the fine lines should be maintained. With line widths of about 40 μm, these heights should exceed about 12 μm to deliver an aspect ratio (AR) of about ≥0.3.

The rheology of the organic vehicle should provide shear thinning and settling properties without excessive spreading after the inventive conductive paste composition is applied to the wafer. Using binder materials may provide particle-to-particle cohesion that keeps the conductive paste composition from breaking apart (“binder”, as used herein, refers to the organic components of the organic vehicle system that result in particle-to-particle interaction. This may include the resins, rosins and thixotropes). Cohesion reduces the shading of the cell by limiting spreading and retaining straight line edges. The selection of the chain length of the binder material, its degree of substitution of hydroxyl, groups and the percent loading of these binders can impact the line spreading and influence how clean the line edges are.

Following the drying of the conductive paste composition on the front side of the wafer, the wafer may be “fast fired” in which it reaches peak temperature near 800° C. The wafer is then rapidly cooled, e.g., in less than one minute, to room temperature. During this firing step, the aluminum paste reaches a eutectic point with the silicon and functions as a dopant to form a p+ back surface electric field, which drives electrical current in the preferred direction. Also, the amorphous dielectric anti-reflection coating bonds to the silicon. During the firing step, electrodes are formed between the wafer and the inventive conductive paste composition. The organic binder in the conductive paste volatilizes, and excess carbon is taken away by the oxygen provided by materials in the conductive paste composition.

Additives that flow to the surface of the silicon wafers etch through the insulating oxide and/or nitride ARC layers. The matrix of additives and glass that remain among the metal increases the cohesive network strength of the fired conductive paste composition. The network aids in the adhesion properties to the interconnect wires that will be soldered to the bus bar sections of the finished cell. The conductive powders either sinter into bulk metals, form colloids suspended in the additive and glass matrix at the interface with the silicon, or recrystallize onto the surface of the silicon. The silver crystallites provide the pathway for electrical current to move from the silicon into the bulk silver of the overlying silver grid. The fired silver grid acts as an electrical current collector and feeds the current to the printed front bus bars pads.

Conduction across the silicon/metal/glass/metal portion of the electrode is related to the efficiency of the solar cell in converting light into electrical power. Reducing the thickness of the glassy layer should reduce circuit resistance and therefore improve solar cell efficiency. By including inorganic additives in the inventive conductive paste compositions in lieu of glass, thereby reducing the amount of glass in the paste and by extension in the electrode after formation thereof on the silicon wafer, it is believed that a reduction in the thickness of the glassy layer is achieved. Further, the composition of the inorganic additive in the conductive paste composition may impact the magnitude of colloidal silver particle loading, solubility of the silver in the inorganic additive, and the segregation influences of the silver to crystallize onto the silicon surface. For example, the segregation influence can be observed upon removal of the paste, in the density and size of silver islands that appear on the surface of the wafer. A high density and small size is the preferred result. Conductivity across this region is measured as contact Resistance (R_{C}), which is inversely proportional to the fill factor (FF). Power in the solar cell is calculated by multiplying the short circuit current (I_{SC}) by the open circuit voltage (V_{OC}) by the FF ((I_{SC})×(V_{OC})×(FF)). Cell efficiency is determined by normalizing the power to the cell area.

While the present inventive conductive paste compositions are described in relation to photovoltaic devices such as solar cell, they have other useful applications. For example, they can find use in the preparation of optically reflective applications, sealing glass pastes, etchant pastes, conductive pastes used for shielding purposes, and carrying electrical current in electronic circuit or inductive applications.

The invention is further described by the examples given below.

### EXAMPLES

### Example 1: Procedure for Making Ag-Containing Conductive Paste Compositions

Step 1: A formulation for an organic medium is shown in Table 1. The organic medium is made by dissolving the resins and rosins in the solvent solution (ingredients 1-4) at 60° C. while mixing. After returning to room temperature, the thixotropic agent (ingredient 5) is added to the mixture and the mixture is slowly brought to 60° C. while mixing. It is held at 60° C. for 30 minutes before cooling.

TABLE 1
Vehicle formulation used in pastes discussed in the following Examples.

| | Ingredient | wt. % |
|---|---|---|
| 1 | 2,2,4-Trimethylpentanediol diisobutyrate | 41.0 |
| 2 | 2-(2-Butoxyethoxy)ethyl acetate | 34.0 |
| 3 | Ester of Hydrogenated rosin | 9.0 |
| 4 | Ethyl cellulose 48.0-49.5 Ethoxyl % | 3.0 |
| 5 | Micronized amide wax rheology modifier | 13.0 |
| | Total | 100.0 |

Step 2: The organic medium is mixed with the dispersant, additives and glass identified in Table 2 (ingredients 1-8) until the blend is homogenous.

TABLE 2
Silver paste formulation used in conductive paste compositions
discussed in the following Examples.

| | Ingredient | wt. % |
|---|---|---|
| 1 | Table 1 Organic Medium | 4.859 |
| 2 | Dispersant | 1.4 |
| 3 | Zinc oxide, ZnO | 0.3 |
| 4 | Lithium phosphate, LiPO₄ | 0.15 |
| 5 | Bismuth oxide, Bi₂O₃, nano-powder | A |
| | (36 nm) | |
| 6 | Lead oxide, PbO | B |
| 7 | Tellurium oxide, TeO₂ | C |
| 8 | Glass | 1.691 Minus (A + B + C) - |
| | | see Table 3 |
| 9 | Ag powder | 90.6 |
| 10 | Withheld solvent and/or vehicle | 1.0 |
| | Total | 100.0 |

Step 3: The silver powder (ingredient 9) is then added and mixed until the powder is wet out and no clumps remain.

Step 4: The paste viscosity is tested on a TA Rheometer at 10 reciprocal seconds.

Step 5: The viscosity of the paste is adjusted using ingredient 10 of Table 2 according to the following: the amount of solvent, 2,2,4-trimethylpentanediol diisobutyrate is added based upon the measured viscosity. Approximately 0.1 wt % of the solvent lowers the viscosity by 10 Pa-s. Adequate solvent is added to reach the target viscosity of 140 Pa-s (±10) at 10 reciprocal seconds using a zero degree cone and plate on an AR-2000EX rheometer from TA Instruments or similar. The vehicle has minimal impact on the paste viscosity. The remainder of the 1% withheld material comes from the vehicle, which is added at an appropriate amount to bring the paste up to 100 wt %.

Step 6: The mixture from Step 5 is then processed in multiple passes on a three-roll mill where particles in the mixture are further de-agglomerated and dispersed. Using the 4^{th} scratch method for measuring the ‘fineness of grind’, the paste should reach preferred particle size of <15μm. The preferred viscosity of the conductive paste compositions thus prepared at 10/s and 25° C. is about 100 Pa*s to about 200 Pa*s, more preferably about 130 Pa*s to about 150 Pa*s as measured using a zero degree cone and plate on an AR-2000EX rheometer from TA Instruments.

### Example 2: Fabrication of Solar Cells and Electrical Performance Testing

In the test examples given below, the silicon wafers used are mono-crystalline, 125 mm×125 mm, and have an emitter sheet resistance of 80±10 Ohm/square. Preparation includes the following steps.
1) 1.0 g of Al paste is screen printed on the entire back-side of each silicon wafer except for a margin of about 1.5 mm around the edge. The screen parameters used for printing Al paste are: 325mesh, 0.9 mil wire diameter, 10 μm emulsion-over-mesh (EOM), and a 45° bias. The squeegee shore hardness is 80. Cells are then dried in a BTU International D914 dryer with a belt speed of 90 inches per minute, ipm, and zone temperatures settings of 310° C., 290° C., and 285° C.
2) The conductive paste composition is screen printed on the front surface of the silicon wafers. The screen printing parameters are: 360mesh, 0.6 mil wire diameter, and 15 μm EOM and a 22.5° bias. The squeegee shore hardness is 70. Fine finger line openings on the screen are held at 45 μm. The cells are dried at a belt speed of 165 inches per minute (imp) with zones 1-3 set at the respective temperatures of 340° C., 370° C. and 370° C.
3) The metallized wafers are fired in a BTU International PV309 firing furnace at a belt speed of 200 ipm and zones 1-4 set at 850° C., 790° C., 880° C. and 1000° C.

A Solar Simulator/I-V tester from PV Measurements Inc. is used to measure the electrical performance metrics of open-circuit voltage (V_{OC}), short-circuit current (I_{SC}), fill factor (FF), efficiency (Eff), and series and shunt resistances (R_{S}, R_{SH}). The illumination of the lamp is calibrated using a sealed calibration cell with the measured characteristics adjusted to the standard AM1.5 spectral conditions at 1000 mW/cm². During testing, cells are positioned on a vacuum chuck under the lamp with the chuck temperature maintained at 25° C. Both dark and light I-V curves are collected by sweeping voltage between −0.2V up to +1.2V and measuring the current output. The results are obtained using commercially available computer software.

A Suns-Voc tester, available from Sinton Instruments, is used to evaluate shunting and recombination mechanisms that may be associated to the metallization pastes. Cells are placed onto a base plate probe and the top-side bus bar is contacted with a probe. The cell voltage is measured as the cell is subjected to a variable light intensity pulse, thus providing a voltage versus light intensity curve. Sinton software calculates cell performance metrics from this data. The relevant metrics reported below include the pseudo-efficiency (Ps-Eff), ‘0.1 Sun V_{OC}’ and the electrical current recombination metric ‘J_{O2}’.

### Example 3: Additives Delivering Low-Resistance Electrical Contact and High-Efficiency Cell

Glasses were prepared by mixing varied amounts of PbO, TeO₂, Bi₂O₃, and Tl₂O₃. One kilogram of the oxide mixtures were heated in alumina crucibles to 900° C. for one hour and the melt was sparged with oxygen. The melted glass mixture was then poured into deionized water to quench it into a frit. The material was ball milled with zirconia media to lower the particle size distribution to a D50 value below 2.0 μm. The media was then removed and the remaining powder was dried.

Conductive paste compositions are made according to the process set forth in Steps 1 thru 6 of Example 1. Table 3 provides the amount of additives used in each of the pastes as designated by the variables ‘A’, ‘B’ and ‘C’ for ingredients 5, 6, and 7 in Table 2. Conductive paste compositions were made with one or more glasses, the compositions of which are reported in Table 4. The glass component follows the recipe of ingredient 8 in Example 1.

Paste 98A is a reference paste with a glass loading of 1.68 wt %. Pastes 98B to 98P are used to evaluate different pathways to supplant glass with additives. Whether in bound or free states, as glass or additive forms, the wt % of the Bi₂O₃, PbO, TeO₂ and Tl₂O₃ were held constant in the paste compositions shown in Table 3. The impact from the total amount of glass replaced, and how the ratio of free to bound material impacts the electrical performance were evaluated.

The amount of inorganic additives in pastes 98B to 98P ranges from 1.519 wt % to 0.15 wt % and as free components they are present from 0.23 wt % to 1.76 wt %. The free to bound ratios (for example, the wt % bismuth oxide as additive divided by wt % bismuth oxide as glass) for Bi₂O₃, PbO and TeO₂ are also shown in Table 3. For the non-reference pastes 98B thru 98P, the free to bound Bi₂O₃ ranges from 0.12 to 10.21, for PbO it goes from 0.00 to infinity and for TeO₂ it spans 0.00 to 14.58.

TABLE 3
Inorganic Additives in the Formulations

| | Additive Wt % (Free) | | | | Glass Wt % (Bound) | | | | | | | | Wt % Total |
|---|---|---|---|---|---|---|---|---|---|---|---|---|---|
| | | | | Total | | | | | Total | Free to Bound Ratio | | | Additives |
| Paste | A = Bi₂O₃ | B = PbO | C = TeO₂ | Wt % | Bi₂O₃ | PbO | TeO₂ | Tl₂O₃ | Wt % | Bi₂O₃ | PbO | TeO₂ | cited + Glass |
| 98A | 0.011 | — | — | 0.011 | 0.207 | 0.664 | 0.72 | 0.084 | 1.680 | 0.05 | — | — | 1.691 |
| 98B | 0.183 | 0.664 | 0.573 | 1.421 | 0.035 | — | 0.151 | 0.084 | 0.271 | 5.22 | ∞ | 3.78 | 1.691 |
| 98C | 0.199 | 0.664 | 0.678 | 1.541 | 0.020 | — | 0.047 | 0.084 | 0.150 | 10.21 | ∞ | 14.58 | 1.691 |
| 98D | 0.168 | 0.603 | 0.521 | 1.291 | 0.051 | 0.061 | 0.204 | 0.084 | 0.400 | 3.28 | 9.91 | 2.55 | 1.691 |
| 98F | 0.168 | 0.555 | 0.567 | 1.291 | 0.050 | 0.109 | 0.157 | 0.084 | 0.400 | 3.35 | 5.11 | 3.61 | 1.691 |
| 98G | 0.138 | 0.486 | 0.420 | 1.043 | 0.081 | 0.178 | 0.305 | 0.084 | 0.648 | 1.69 | 2.73 | 1.38 | 1.691 |
| 98H | 0.149 | 0.486 | 0.497 | 1.132 | 0.070 | 0.178 | 0.228 | 0.084 | 0.560 | 2.13 | 2.73 | 2.18 | 1.691 |
| 98J | 0.060 | 0.190 | 0.164 | 0.414 | 0.158 | 0.474 | 0.561 | 0.084 | 1.277 | 0.38 | 0.40 | 0.29 | 1.691 |
| 98K | 0.065 | 0.189 | 0.194 | 0.448 | 0.154 | 0.474 | 0.531 | 0.084 | 1.243 | 0.42 | 0.40 | 0.37 | 1.691 |
| 98L | 0.184 | 0.552 | 0.673 | 1.409 | 0.035 | 0.112 | 0.052 | 0.084 | 0.282 | 5.27 | 4.95 | 12.98 | 1.691 |
| 98M | 0.184 | 0.622 | 0.603 | 1.409 | 0.035 | 0.042 | 0.122 | 0.084 | 0.282 | 5.27 | 14.94 | 4.95 | 1.691 |
| 98N | 0.023 | 0.149 | — | 0.172 | 0.196 | 0.515 | 0.725 | 0.084 | 1.519 | 0.12 | 0.29 | — | 1.691 |
| 98P | 0.025 | — | 0.159 | 0.183 | 0.194 | 0.664 | 0.566 | 0.084 | 1.508 | 0.13 | — | 0.28 | 1.691 |

Table 4 shows the unit conversion between the wt % in the conductive paste composition and the relative wt % and mol % present in the glass.

TABLE 4
Glass Formulations, Re-Stated In Terms of Relative Weight And Molar Percentages

| | Wt % | | | | | | | | | | |
|---|---|---|---|---|---|---|---|---|---|---|---|
| | Glass in | Wt % in Glass | | | | | Mol % in Glass | | | | |
| Paste | paste | Bi₂O₃ | PbO | TeO₂ | Tl₂O₃ | Total | Bi₂O₃ | PbO | TeO₂ | Tl₂O₃ | Total |
| 98A | 1.68% | 12% | 40% | 43% | 5% | 100% | 5% | 37% | 56% | 2% | 100% |
| 98B | 0.27% | 13% | 0% | 56% | 31% | 100% | 6% | 0% | 79% | 15% | 100% |
| 98C | 0.15% | 13% | 0% | 31% | 56% | 100% | 8% | 0% | 56% | 36% | 100% |
| 98D | 0.40% | 13% | 15% | 51% | 21% | 100% | 6% | 15% | 69% | 10% | 100% |
| 98F | 0.40% | 13% | 27% | 39% | 21% | 100% | 6% | 28% | 56% | 10% | 100% |
| 98G | 0.65% | 13% | 27% | 47% | 13% | 100% | 6% | 26% | 62% | 6% | 100% |
| 98H | 0.56% | 12% | 32% | 41% | 15% | 100% | 6% | 31% | 56% | 7% | 100% |
| 98J | 1.28% | 12% | 37% | 44% | 7% | 100% | 6% | 34% | 57% | 3% | 100% |
| 98K | 1.24% | 12% | 38% | 43% | 7% | 100% | 6% | 36% | 56% | 3% | 100% |
| 98L | 0.28% | 12% | 40% | 18% | 30% | 100% | 7% | 46% | 30% | 17% | 100% |
| 98M | 0.28% | 12% | 15% | 43% | 30% | 100% | 6% | 15% | 63% | 15% | 100% |
| 98N | 1.52% | 13% | 34% | 48% | 6% | 100% | 6% | 31% | 61% | 2% | 100% |
| 98P | 1.51% | 13% | 44% | 38% | 6% | 100% | 6% | 42% | 50% | 3% | 100% |

TABLE 5
Average Electrical Performance Metrics for 10 Cells of Each of
the 98 Series Conductive Paste Compositions
Electrical Performance Metrics

| | | | | | | | I_{REV} | | | |
|---|---|---|---|---|---|---|---|---|---|---|
| | I_{SC} | V_{OC} | FF | Eff | R_{S} | R_{SH} | @ −12 V | Ps-Eff | 0.1 sun | J_{O2} |
| Paste | (A) | (V) | (%) | (%) | (Ohm) | (Ohm) | (A) | (%) | V_{OC} (V) | (nA/cm²) |
| 98A | 5.78 | 0.637 | 77.5 | 18.45 | 1.04 | 10032 | −0.10 | 19.4 | 0.566 | 3.74 |
| 98B | 5.79 | 0.637 | 77.3 | 18.45 | 1.09 | 6323 | −0.20 | 19.4 | 0.566 | 2.57 |
| 98C | 5.80 | 0.637 | 76.9 | 18.36 | 1.17 | 6064 | −0.19 | 19.4 | 0.566 | 2.21 |
| 98D | 5.80 | 0.637 | 77.4 | 18.46 | 1.09 | 7411 | −0.18 | 19.5 | 0.566 | 1.72 |
| 98G | 5.78 | 0.637 | 77.5 | 18.43 | 1.06 | 8317 | −0.13 | 19.4 | 0.566 | 3.29 |
| 98H | 5.78 | 0.637 | 77.5 | 18.43 | 1.06 | 8943 | −0.13 | 19.4 | 0.566 | 2.28 |
| 98J | 5.79 | 0.637 | 77.6 | 18.48 | 1.05 | 12103 | −0.10 | 19.5 | 0.566 | 2.77 |
| 98K | 5.82 | 0.637 | 77.5 | 18.56 | 1.06 | 12438 | −0.08 | 19.5 | 0.567 | 1.97 |
| 98L | 5.78 | 0.637 | 77.2 | 18.36 | 1.13 | 8806 | −0.11 | 19.4 | 0.566 | 1.38 |
| 98M | 5.81 | 0.637 | 77.5 | 18.54 | 1.06 | 9911 | −0.16 | 19.5 | 0.567 | 1.35 |
| 98N | 5.79 | 0.637 | 77.3 | 18.41 | 1.10 | 13749 | −0.09 | 19.4 | 0.566 | 3.83 |
| 98P | 5.80 | 0.637 | 77.5 | 18.51 | 1.06 | 10783 | −0.09 | 19.5 | 0.567 | 3.34 |

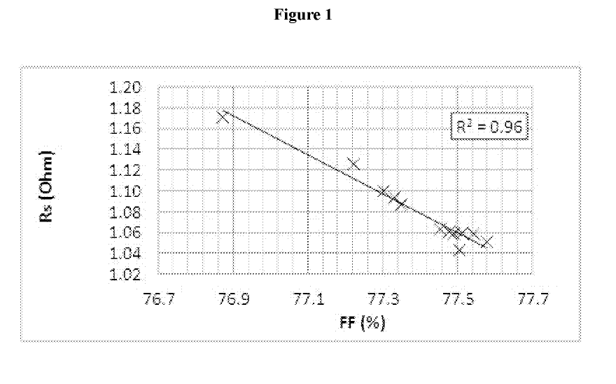

Table 5 reports the average measured electrical response for ten (10) cells prepared from each conductive paste composition. Since efficiency, Eff, is proportional to the product of I_{SC}, V_{OC} and FF, it is important to note that the intended primary impact from the paste is on the FF. The function of modifying the paste is to lower the contact resistance portion of the series resistance, R_{S}, which in turn impacts the FF. While other factors such as R_{SH} and J₀₂ can impact the FF, it was observed that R_{S} drives the FF values in this study through the strong correlation shown in FIG. 1. Therefore, particular attention is paid to the R_{S} response from paste to paste, as it is the key indicator for contact resistance. By delineation as the R_{S} value decreases, the contact resistance is improved, such that smaller R_{S} numbers are preferred.

In comparing the wt % of glass to electrical performance between Tables 3 and 5, there is no correlation that indicates using more glass improves performance. Electrical performance does not rely on the amount of glass but rather on the interaction of the compositions of the additives and the glass. Thus, indicating the feasibility of replacing glass materials with additives as a practical means of achieving good electrical contact to silicon solar cells.

The free to bound ratios for the additives and the glass components were considered. From the electrical response values reported in Table 5 and the free to bound ratios reported in Table 3, the V_{OC} is 0.637V for all conductive paste compositions and variations in I_{SC} are minor compared to those from FF. Similarly, variations in Ps-Eff and J₀₂ are similar for each result. Therefore, the electrical performance metrics are evaluated based solely on the series resistance, R_{S}. Increasing the free to bound ratio for Bi₂O₃ has no negative impact up to at least a ratio of 5 as observed in conductive paste compositions 98B and 98M, and possibly higher. Similarly, the free to bound ratio for PbO has no restrictions from a value of 0.12 in paste 98N to a full replacement of bound PbO in pastes 98B and 98C. Comparing the R_{S} values observed in 98C and 98L to that of 98M, it appears that the free to bound ratio for TeO₂ exhibits good results (similar to comparative example 98A) at a ratio of up to 12, and possibly higher. The free to bound ratio observations above are limited to the confines of the inorganic systems evaluated and are not intended to indicate generalized limitations.

### Example 4: Lowering the Amount of Glass in Conductive Paste Compositions

Comparable series resistance can be delivered when additives are used wholly or in part in place of glass in pastes, as shown in this example. In the conductive paste compositions of this example, the free to bound loading is varied to identify how performance is impacted.

The Example 4 pastes are made identically to the recipe provided in Example 1. The formulation is outlined in Table 6 and the values for the variables, A, B, C, X and Y are provided in Table 7.

TABLE 6
Conductive Paste Compositions used in Example 4

| | Ingredient | wt. % |
|---|---|---|
| 1 | Table 1 Vehicle | 5.12 |
| 2 | Dispersant | 1.4 |
| 3 | Zinc oxide, ZnO | 0.3 |
| 4 | Lithium phosphate, LiPO₄ | 0.15 |
| 5 | Bismuth oxide, Bi₂O₃, nano-powder (36 nm) | A |
| 6 | Lead oxide, PbO | B |
| 7 | Tellurium oxide, TeO₂ | C |
| 8 | Glass | X |
| 9 | Ag powder | 92.03-Y |
| 10 | Deficient (solvent and/or vehicle) | 1.0 |
| | Total | 100.0 |

Conductive paste compositions were prepared in which the glass amount varied from 0.55 wt % to 0.00 wt %, with the bound glass components being replaced by free inorganic additives. The total amount of additives and glass is not held constant like in the 98 series of pastes. The range of free to bound ratios for the Bi₂O₃ and TeO₂ are expanded compared to the 98 series while the free to bound PbO still ranges from zero to infinity.

The same glass is used for all pastes, which was also used for paste 98M of Example 3. The silver wt % was adjusted in order to hold the solids loading constant for all pastes, where the total ‘solids’ comprise ingredients 3 thru 10 in Table 6. Maintaining a constant solids load helps normalize the printability of the pastes to minimize pate to paste differences in I_{SC}.

TABLE 7
Wt % and Free To Bound Ratios for the Conductive Paste Compositions of Example 4

| | Additives Wt % | | | | Glass Wt % | | | | | | | | Y = Total Wt % |
|---|---|---|---|---|---|---|---|---|---|---|---|---|---|
| | | | | Total | | | | | X = Total | Free to Bound Ratio | | | Additives + Glass |
| Paste | A = Bi₂O₃ | B = PbO | C = TeO₂ | Wt % | Bi₂O₃ | PbO | TeO₂ | Tl₂O₃ | Wt % | Bi₂O₃ | PbO | TeO₂ | (A + B + C + X) |
| 113 Ref | 0.011 | — | — | 0.011 | 0.207 | 0.664 | 0.725 | 0.084 | 1.680 | 0.05 | — | — | 1.691 |
| 98M | 0.184 | 0.622 | 0.603 | 1.409 | 0.035 | 0.042 | 0.122 | 0.084 | 0.282 | 5.27 | 14.94 | 4.95 | 1.691 |
| 113A | 0.143 | 0.590 | 0.573 | 1.306 | 0.034 | 0.040 | 0.118 | 0.082 | 0.274 | 4.21 | 14.57 | 4.85 | 1.580 |
| 113B | 0.116 | 0.424 | 0.479 | 1.018 | 0.061 | 0.073 | 0.213 | 0.147 | 0.494 | 1.90 | 5.81 | 2.25 | 1.512 |
| 113C | 0.129 | 0.507 | 0.526 | 1.162 | 0.047 | 0.057 | 0.166 | 0.114 | 0.384 | 2.72 | 8.94 | 3.18 | 1.546 |
| 113D | 0.156 | 0.673 | 0.621 | 1.450 | 0.020 | 0.024 | 0.071 | 0.049 | 0.165 | 7.69 | 27.69 | 8.75 | 1.614 |
| 113F | 0.170 | 0.756 | 0.668 | 1.594 | 0.007 | 0.008 | 0.024 | 0.016 | 0.055 | 25.07 | 93.33 | 28.24 | 1.648 |
| 113G | 0.177 | 0.797 | 0.692 | 1.666 | — | — | — | — | — | ∞ | ∞ | ∞ | 1.666 |

From the electrical response values reported in Table 8, the V_{OC} and I_{SC} are similar for all conductive paste compositions while the paste-to-paste differences in FF appear to be primarily responsible for the changes to cell efficiency (Eff). Nonetheless, the efficiencies obtained are comparable, thus indicating the success of the approach toward using Free rather Bound oxides to form comparably good electrical contacts to solar cells.

TABLE 8
Electrical Performance Values for the Conductive Paste Compositions of Example 4
Electrical Performance Metrics

| | | | | | | | I_{REV} | | | |
|---|---|---|---|---|---|---|---|---|---|---|
| | I_{SC} | V_{OC} | FF | Eff | R_{S} | R_{SH} | @ −12 V | Ps-Eff | 0.1 sun | J_{O2} |
| Paste | (A) | (V) | (%) | (%) | (Ohm) | (Ohm) | (A) | (%) | V_{OC} (V) | (nA/cm²) |
| 113 | 5.74 | 0.633 | 77.73 | 18.23 | | | | | | |
| Ref¹ | | | | | | | | | | |
| 98M¹ | 5.76 | 0.633 | 77.77 | 18.32 | | | | | | |
| 113A | 5.76 | 0.633 | 77.77 | 18.33 | 0.99 | 7265 | −0.19 | 19.21 | 0.561 | 9.16 |
| 113B | 5.76 | 0.633 | 77.97 | 18.39 | 0.98 | 9093 | −0.15 | 19.27 | 0.562 | 6.77 |
| 113C | 5.76 | 0.633 | 77.98 | 18.37 | 0.98 | 7605 | −0.15 | 19.27 | 0.562 | 6.67 |
| 113D | 5.76 | 0.633 | 77.69 | 18.29 | 1.00 | 6419 | −0.25 | 19.19 | 0.561 | 10.24 |
| 113F | 5.76 | 0.632 | 77.63 | 18.26 | 1.01 | 8185 | −0.15 | 19.19 | 0.560 | 10.21 |
| 113G | 5.76 | 0.632 | 77.33 | 18.20 | 1.02 | 9005 | −0.16 | 19.12 | 0.559 | 14.16 |

The 113 Ref is a trial-adjusted extrapolation of the comparative example paste 98A. The extrapolation for 98M values is based on average I_{SC} and V_{OC} values from the 113 series and using the FF from the similar paste 113A. The values input for 113 Ref are determined by translating the values from 98A with the same normalization factors used to adjust 113A values to 98M.

Table 8 shows that the conductive paste compositions of the present invention, which replace all or part of the glass (bound) with inorganic oxide additives (free), exhibit comparable series resistance properties.

In addition to making electrical contact, an additional function of the conductive paste composition may be to provide a means to interconnect the solar cells. This entails printing large area solder pads onto the faces of the cell. These solder pads act as bus bars in which electricity can enter and leave a cell. The glass in the paste has historically played a major part in determining the adhesion strength between the bus bar and ribbons that inter-connect the cells.

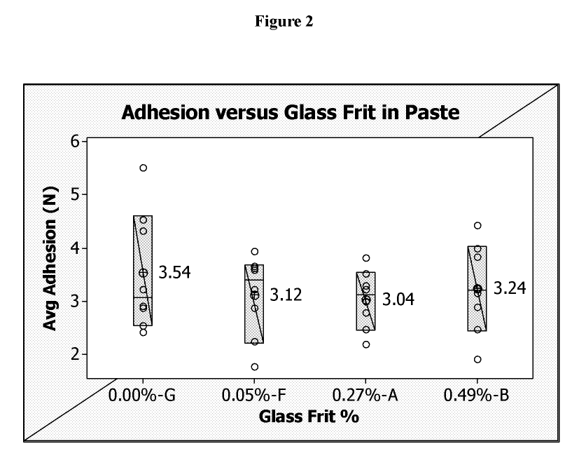

Standard 180° peel strength methods are used to test adhesion between the ribbons and the bus bars of the solar cells using an Instron load cell. The fired paste constitutes the bus bars. Four pastes with different amounts of glass, and Free to Bound ratios were tested. The adhesion strength (N), i.e., Newtons) was averaged across each of eight bus bars tested for each paste. FIG. 2 shows the adhesion between the tabbing ribbons and bus bars of multiple cells measured for pastes 113A, B, G, and F, and shows the distribution of the eight data points for each paste and reports the mean value for each paste along with the wt % glass in each paste. The results surprisingly indicate that the loading level of glass, or lack thereof, does not impact this adhesion. Therefore replacing Bound with Free state material does not degrade the secondary function of the pastes made with zero glass.

### Example 5: Changing the Ratio of TeO₂ to Tl₂O₃ in the Conductive Paste Compositions

Conductive paste compositions were prepared in which the amounts of Tl₂O₃ and TeO₂ were varied from composition to composition, and the performance characteristics of the compositions was assessed based on the ratio of TeO₂ to Tl₂O₃.

Conductive paste compositions were prepared as described in Example 1 using the components and amounts thereof set forth in Table 9. Glass frit was prepared as described in Example 3. Solar cells were prepared from these pastes as set forth in Example 2. The amounts of PbO and Bi₂O₃ in the glass were held constant, and as indicated, the amounts of TeO₂ and Tl₂O₃, expressed as the ratio on a weight percentage basis of TeO₂ to Tl₂O₃ (wt % ratio) were varied, as shown in Table 10.

TABLE 9
Ingredients for Conductive Paste Compositions used in Example 5

| | Ingredient | wt. % |
|---|---|---|
| 1 | Table 1 Vehicle | 6.2 |
| 2 | Dispersant | 1.5 |
| 3 | Additives; ZnO + Li₃PO₄ | 0.34 |
| 4 | Glass containing Tl₂O₃ + TeO₂ + PbO + Bi₂O₃ | 1.96 |
| 5 | Ag powder | 89.0 |
| 6 | Withheld solvent and/or vehicle | 1.0 |
| | Total | 100.0 |

TABLE 10
Weight % of Inorganic Components in Example 5 Conductive Paste
Compositions

| | | | Bi₂O₃ + | | |
|---|---|---|---|---|---|
| Paste | TeO₂ | Tl₂O₃ | PbO | Li₃PO₄ + ZnO | TeO₂:Tl₂O₃ |
| 25A | 19.699% | 33.730% | 32.183% | 14.388% | 0.58 |
| 25B | 33.105% | 20.342% | 32.165% | 14.388% | 1.63 |
| 25C | 34.435% | 19.077% | 32.101% | 14.388% | 1.81 |
| 25D | 36.024% | 17.585% | 32.003% | 14.388% | 2.05 |
| 25F | 36.925% | 16.718% | 31.969% | 14.388% | 2.21 |
| 25G | 37.655% | 15.686% | 32.271% | 14.388% | 2.40 |
| 25H | 39.039% | 14.499% | 32.074% | 14.388% | 2.69 |
| 25I | 40.299% | 13.711% | 31.601% | 14.388% | 2.94 |
| 25J | 53.010% | 0.572% | 32.030% | 14.388% | 92.64 |

TABLE 11
Mol % of Inorganics in the Example 5 Paste Compositions

| | | | | Li3PO4 + | |
|---|---|---|---|---|---|
| Paste | TeO2 | Tl2O3 | Bi2O3 + PbO | ZnO | TeO2:Tl2O3 |
| 25A | 27.047% | 16.182% | 40.060% | 16.711% | 1.67 |
| 25B | 40.595% | 8.716% | 35.764% | 14.925% | 4.66 |
| 25C | 41.781% | 8.088% | 35.393% | 14.738% | 5.17 |
| 25D | 43.170% | 7.363% | 34.945% | 14.521% | 5.86 |
| 25F | 43.938% | 6.951% | 34.711% | 14.399% | 6.32 |
| 25G | 44.558% | 6.486% | 34.511% | 14.446% | 6.87 |
| 25H | 45.706% | 5.931% | 34.152% | 14.211% | 7.71 |
| 25I | 46.731% | 5.556% | 33.828% | 13.886% | 8.41 |
| 25J | 56.102% | 0.212% | 30.844% | 12.842% | 265.13 |

TABLE 12
Weight % of Inorganics in the Glass of Example 5 Paste Compositions

| Paste | TeO₂ | Tl₂O₃ | Bi₂O₃ + PbO | TeO₂:Tl₂O₃ |
|---|---|---|---|---|
| 25A | 23.010% | 39.399% | 37.591% | 0.58 |
| 25B | 38.668% | 23.761% | 37.571% | 1.63 |
| 25C | 40.222% | 22.283% | 37.496% | 1.81 |
| 25D | 42.078% | 20.540% | 37.381% | 2.05 |
| 25F | 43.130% | 19.528% | 37.342% | 2.21 |
| 25G | 43.983% | 18.322% | 37.695% | 2.40 |
| 25H | 45.599% | 16.936% | 37.465% | 2.69 |
| 25I | 47.072% | 16.016% | 36.912% | 2.94 |
| 25J | 61.919% | 0.668% | 37.412% | 92.64 |

TABLE 13
Mol % of Inorganics in the Glass of Example 5 Paste Compositions

| Paste | TeO₂ | Tl₂O₃ | Bi₂O₃ + PbO | TeO₂:Tl₂O₃ |
|---|---|---|---|---|
| 25A | 39.022% | 23.347% | 37.632% | 1.67 |
| 25B | 55.923% | 12.007% | 32.070% | 4.66 |
| 25C | 57.328% | 11.097% | 31.574% | 5.17 |
| 25D | 58.963% | 10.057% | 30.979% | 5.86 |
| 25F | 59.858% | 9.470% | 30.672% | 6.32 |
| 25G | 60.581% | 8.818% | 30.601% | 6.87 |
| 25H | 61.906% | 8.034% | 30.060% | 7.71 |
| 25I | 63.080% | 7.499% | 29.421% | 8.41 |
| 25J | 73.485% | 0.277% | 26.238% | 265.13 |

From the electrical response values reported in Table 14, the V_{OC} and I_{SC} are similar for all conductive paste compositions. Pastes 25A and 25J, the outer ratios of TeO₂ to Tl₂O₃, e.g., 0.6 and 93 respectively, have larger values for series resistance, R_{S}, which cause the subsequent decrease in FF and Eff values. There is approximately a 0.2% drop in efficiency in the 25J (at a ratio of 93) compared to the pastes with TeO₂:Tl₂O₃ ratios between 1.3 and 2.9. This difference in efficiency provides an indication of the improvement believed to be due to including the thallium component. Similarly, the drop in efficiency observed from 25A relative to the other paste compositions is believed to be due to including the tellurium component. The inclusion of both a thallium component and a tellurium component tellurium in the conductive paste compositions improves the efficiency of the cell.

TABLE 14
Effect on Series Resistance and Fill Factor from Adjusting the
Ratio of TeO₂ to Tl₂O₃ (Average of 10 Solar Cells)
Electrical Performance

| Paste | TeO₂:Tl₂O₃ | I_{SC} | V_{OC} | FF | Eff | R_{S} |
|---|---|---|---|---|---|---|
| 25A | 0.6 | 8.95 | 0.624 | 66.93 | 15.46 | 3.30 |
| 25B | 1.3 | 8.97 | 0.626 | 79.65 | 18.48 | 0.635 |
| 25C | 1.6 | 8.95 | 0.626 | 79.68 | 18.46 | 0.620 |
| 25D | 2 | 8.94 | 0.627 | 79.69 | 18.44 | 0.627 |
| 25F | 2.2 | 8.95 | 0.627 | 79.73 | 18.48 | 0.625 |
| 25G | 2.4 | 8.94 | 0.626 | 79.68 | 18.44 | 0.616 |
| 25H | 2.7 | 8.93 | 0.626 | 79.71 | 18.43 | 0.621 |
| 25I | 2.9 | 8.93 | 0.626 | 79.73 | 18.43 | 0.623 |
| 25J | 93 | 8.91 | 0.628 | 78.89 | 18.25 | 0.797 |

It was found that the presence of each of Tl₂O₃ and TeO₂ improves the series resistance of the conductive paste compositions. The improvement can be seen for example when the ratio of TeO₂ to Tl₂O₃ is in the range of 0.6 to 93 on a weight percentage basis. Due to the magnitude of the improvement, it may be that the lower contact resistance between the fired electrode paste and the silicon solar cell is the cause of the improvement. The presence of the Tl₂O₃ may lower glass transition temperature and flow properties, such that better electrical contacts can be made.

The present invention has been described in detail, including the preferred embodiments thereof. However, it will be appreciated that those skilled in the art, upon consideration of the present disclosure, may make modifications and/or improvements on this invention that fall within the scope and spirit of the invention.

1. A conductive composition comprising:
a silver powder;
an organic medium;
an optional inorganic additive;
elemental thallium and/or a thallium containing compound;
elemental tellurium and/or a tellurium containing compound;
and optionally, a glass frit.

2-51. (canceled)

52. The conductive composition of claim 1, wherein the elemental thallium and/or thallium containing compound comprises thallium oxide.

53. The conductive composition of claim 1, wherein the elemental tellurium and/or tellurium containing compound comprises tellurium oxide.

54. The conductive composition of claim 1, wherein the inorganic additive comprises the elemental thallium and/or thallium containing compound.

55. The conductive composition of claim 1, wherein the inorganic additive comprises thallium oxide.

56. The conductive composition of claim 1, wherein the inorganic additive comprises the elemental tellurium and/or tellurium containing compound.

57. The conductive composition of claim 54, wherein the inorganic additive comprises the elemental tellurium and/or tellurium containing compound.

58. The conductive composition of claim 1, wherein the inorganic additive comprises tellurium oxide.

59. The conductive composition of claim 1, wherein the glass frit comprises the elemental thallium and/or thallium containing compound.

60. The conductive composition of claim 1, wherein the glass frit comprises thallium oxide.

61. The conductive composition of claim 1, wherein the glass frit comprises the elemental tellurium and/or tellurium containing compound.

62. The conductive composition of claim 59, wherein the glass frit comprises the elemental tellurium and/or tellurium containing compound.

63. The conductive composition of claim 1, wherein the glass frit comprises tellurium oxide.

64. The conductive composition of claim 1, wherein at least one of the inorganic additive and glass frit comprise one or more components selected from a bismuth containing compound, a lead containing compound, a lithium containing compound, a zinc containing compound, a tellurium containing compound, a thallium containing compound, bismuth oxide, lead oxide, lithium phosphate, zinc oxide, tellurium oxide, thallium oxide, a chalcogenide, a pnicogenide, a halide, Ag₂Te, AgAsF₆, Ag₃AsO₄, AgBF₄, AgBr, AgCl, AgClO₄, AgF, AgF₂, AgHF₂, AgI, Ag₂MoO₄, AgPF₆, AgPO₄, AgReO₄, Ag₂SO₄, Ag₂S, AgSbF₆, AgVO₃, Ag₂WO₄, Al₂O₃, As₂O₃, AuTe₂, BaO, B₂O₃, BaF₂, BaO, Bi, BiBr₃, BiCl₃, BiF₃, Bi₄Ge₃O₁₂, BiI₃, Bi₂MoO₆, Bi₂Mo₃O₁₂, Bi₂O₃, Bi(OH)₃, BiSb, Bi₂Se₃, Bi₂S₃, Bi₂Te₃, BiVO₄, Bi₂(WO₄)₃, C₂O₃, CaO, CdO, CoO, CuO, Cu₂O, Ga₂O₃, In₂O₃, KAg₄I₅, LaF₃, La₂O₃, Li₂O, Li₃PO₄, MgO, Mn₂O₅, MnO₂, Mo₂O₃, NiO, P₂O₅, Pb, PbBr₂, PbCl₂, PbF₂, PbHPO₄, PbI₂, PbO, Pb SO₄, Pb Se, PbS, PbSb, PbTe, Pb(VO₃)₂, ReO₂, ReO₃, Re₂O₇, RuO₂, Sb₂O₃, SeO₂, SO₂, SO₃, SiO₂, SnO₂, SrF₂, SrO, Tb₂O₃, Tb₄O₇, TiO₂, TlF, Tl₂O₃, OsO₄, V₂O₅, WO₃, Y₂O₃, ZnO, ZnTe, and ZrO₂.

65. The conductive composition of claim 1, wherein the ratio on a weight basis of the elemental tellurium and/or tellurium containing compound to the elemental thallium and/or thallium containing compound in the conductive composition is about 0.6 to about 93.

66. The conductive composition of claim 1, wherein elemental thallium or the thallium containing compound is present in an amount of about 0.01 wt % to about 5 wt %.

67. The conductive composition of claim 1, wherein tellurium oxide is present in an amount of about 0.05 wt % to about 2.5 wt %.

68. The conductive composition of claim 1, wherein the inorganic additive is present in an amount of about 0.1 wt % to about 5.0 wt %.

69. The conductive composition of claim 1, wherein lead oxide is present in an amount of about 0.05 wt % to about 2.5 wt %.

70. The conductive composition of claim 1, wherein bismuth oxide is present in an amount of about 0.01 wt % to about 2.5 wt %, preferably about 0.05 wt % to about 0.5 wt %.

71. The conductive composition of claim 1, wherein glass frit is present in an amount of about 0.01 wt % to about 5.0 wt %.

72. The conductive composition of claim 1, wherein the conductive composition is essentially glass free.

73. The conductive composition of claim 1, wherein tellurium oxide is present in the glass frit in an amount of about 20 wt % to about 70 wt %

74. The conductive composition of claim 1, wherein thallium oxide is present in the glass frit in an amount of about 1 wt % to about 60 wt %.

75. The conductive composition of claim 1, wherein silver powder is present in an amount of about 40 wt % to about 98 wt %.

76. The conductive composition of claim 1, wherein the composition is a paste.

77. A device coated with the conductive composition of claim 1, wherein the device is selected from a semiconductor, photovoltaic device, and a solar cell.

78. The device of claim 77, further comprising a silicon substrate.
